(19) United States
(12) Patent Application Publication
(10) Pub. No.: US 2016/0197025 A1
(43) Pub. Date: Jul. 7, 2016

(54) Method of Fabricating an Electronic Device

(71) Applicant: DOW CORNING CORPORATION, Midland, MI (US)

(72) Inventors: Dorab Edul Bhagwagar, Saginaw, MI (US); Lyndon Larson, Bay City, MI (US); Kristen Steinbrecher, Midland, MI (US); James Tonge, Sanford, MI (US)

(21) Appl. No.: 14/652,532

(22) PCT Filed: Oct. 29, 2013
(86) PCT No.: PCT/US2013/067181

§ 371 Date: Jun. 16, 2015

Related U.S. Application Data
(60) Provisional application No. 61/739,851, filed on Dec. 20, 2012.

(51) Int. Cl. H01L 23/367; H01L 21/48

(52) U.S. Cl. CPC H01L 23/3675; H01L 21/4882

(57) ABSTRACT

A silicone composition contains I) a shrink additive and II) a curable polyorganosiloxane composition. A method for fabricating an electronic device includes the steps of: 1) interposing the silicone composition between an IHS and a substrate, 2) curing the curable polyorganosiloxane composition to form a cured silicone product, and 3) removing the shrink additive during and/or after step 2), thereby compressing the IHS to the substrate. Compressing occurs as thickness of the cured silicone product decreases, as compared to thickness of the silicone composition interposed in step 1).

Electronic components such as semiconductors, transistors, integrated circuits (ICs), discrete devices, central processing units (CPUs), memory caches, and others known in the art are designed to operate at a normal operating temperature or within a normal operating temperature range. However, the operation of an electronic component generates heat. If sufficient heat is not removed, the electronic component will operate at a temperature significantly above its normal operating temperature. Excessive temperatures can adversely affect performance of the electronic component and operation of the electronic device associated therewith and negatively impact mean time between failures.

To avoid these problems, heat can be removed by thermal conduction from the electronic component to a heat sink. The heat sink can then be cooled by any convenient means such as convection or radiation techniques. During thermal conduction, heat can be transferred from the electronic component to the heat sink by contact of the heat-generating electronic component and either an Integrated Heat Spreader (IHS), or a heat sink, with a thermal interface material. Alternatively, the thermal interface material (TIM) may be interposed along a thermal path in the electronic device such that the TIM is in contact with a heat sink and another component in the electronic device that does not generate heat, e.g., an IHS such as a lid or cover. An IHS or heat sink may be attached to the circuit board by a lid seal adhesive. This adhesive serves to mechanically attach the IHS or heat sink above the electronic component on the circuit board.

Surfaces of the electronic component and the IHS or heat sink may not be completely smooth, and therefore, it is difficult to achieve full contact between the surfaces. Air spaces, which are poor thermal conductors, appear between the surfaces and impede the removal of heat. Inserting a TIM between the surfaces of the electronic component and IHS or heat sink can fill these spaces to promote efficient heat transfer. The lower the thermal resistance of the TIM, the greater the heat flow from the electronic component to the heat sink. A higher pressure applied on the TIM will also promote higher heat flow from the electronic component to the IHS or heat sink through the TIM. To improve thermal resistance, pressure can be applied mechanically on the heat sink or IHS using special clips or screws. Pressure can be applied during the curing process or throughout the use of the device.

Multi-chip packages have two or more heat-generating electronic components, e.g., a central processing unit (CPU) and a memory cache, under a single IHS. However, such multi-chip packages place additional requirements on the thermal management solutions. The CPU consumes the largest amount of power and is the component in the multi-chip package that needs to dissipate the highest amount of heat. However, since it is not in the multi-chip package's center, warpage can be generated as a result of mismatches in coefficients of thermal expansion (CTE) of different components in the multi-chip package. This CTE mismatch can place additional stress on the TIMs in the multi-chip package. The memory caches generate lower amounts of heat than the amounts of heat CPUs generate. The memory caches also tend to have a lower profile than profiles of CPUs, thus the TIM associated with the memory cache is usually thicker than the TIM associated with a CPU.

### BRIEF SUMMARY OF THE INVENTION

A method of fabricating an electronic device, the method comprises:

1) interposing a first silicone composition comprising
I) a first shrink additive, and
II) a first curable polyorganosiloxane composition;

between an IHS and a substrate,

2) curing the first curable polyorganosiloxane composition to form a first cured silicone product,

3) removing the first shrink additive during and/or after step 2), thereby compressing the IHS on the substrate.

### BRIEF DESCRIPTION OF THE DRAWINGS

FIG. 1 shows an exemplary multichip package prepared using the first silicone composition and improved method described herein.

### DETAILED DESCRIPTION OF THE INVENTION

For purposes of this application, all amounts, ratios, and percentages are by weight unless otherwise indicated by the context of the specification. The articles, ‘a’, ‘an’ and ‘the’ each refer to one or more unless otherwise indicated by the context of the specification.

“Alkyl” means an acyclic, branched or unbranched, saturated monovalent hydrocarbon group. Examples of alkyl groups include Me, Et, Pr, 1-methylethyl, Bu, 1-methylpropyl, 2-methylpropyl, 1,1-dimethylethyl, 1-methylbutyl, 1-ethylpropyl, pentyl, 2-methylbutyl, 3-methylbutyl, 1,2-dimethylpropyl, 2,2-dimethylpropyl, hexyl, heptyl, 2-ethylhexyl, octyl, nonyl, decyl, undecyl, dodecyl, tetradecyl, hexadecyl, and branched saturated monovalent hydrocarbon groups of 8 to 16 carbon atoms. Alkyl groups have at least one carbon atom. Alkyl groups may have at most 20 carbon atoms. Alternatively, alkyl groups may have 1 to 12 carbon atoms, alternatively 1 to 10 carbon atoms, alternatively 1 to 6 carbon atoms, alternatively 1 to 4 carbon atoms, alternatively 1 to 2 carbon atoms, and alternatively 1 carbon atom.

In the method of fabricating an electronic device, the method comprises:

1) interposing the first silicone composition comprising
I) the first shrink additive, and
II) the first curable polyorganosiloxane composition;

between the IHS and the substrate,

2) curing the first curable polyorganosiloxane composition to form the first cured silicone product,

3) removing the first shrink additive during and/or after step 2), thereby compressing the IHS to the substrate. As used herein, the term “silicone” refers to a polyorganosiloxane macromolecule, or a collection of such macromolecules, wherein each macromolecule independently may be the same or different, including straight chain, branched chain, or cyclic. The first cured silicone product prepared by this method adheres the IHS to the substrate. The IHS is compressed onto the substrate when the first shrink additive is removed because the first cured silicone product shrinks when the first shrink additive is removed. This shrinkage is measured in reduction of the bondline thickness (BLT). Here, BLT refers to the difference between thickness of the first silicone composition interposed between the IHS and the substrate in step 1) compared to thickness of the first cured silicone product between the IHS and the substrate after step 3). Without wishing to be bound by theory, it is thought that this method may provide the benefit that compression (of BLT) can be accomplished without mechanical aids. Without wishing to be bound by theory, it is thought that the thermal properties of the electronic device can be improved, possibly as a result of the compression when the first shrink additive is used in a lid seal adhesive, and that use of a second shrink additive may provide an even further thermal benefit when the second shrink additive is used in the method to form both a lid seal adhesive and a thermal interface material (TIM). Step 3) may be performed both during and after step 2), alternatively step 3) may be performed substantially after, alternatively entirely after, step 2). Performing step 3) substantially after step 2) means at least 90%, alternatively at least 95% of the first shrink additive is removed after step 2) has been completed.

The method may further comprise interposing a second silicone composition between a heat-generating electronic component and a heat dissipater. The heat dissipater may be, for example, the IHS, where the heat-generating electronic component is mounted to the substrate under the IHS. The second silicone composition may be thermally conductive. The method may form a thermally conductive second cured silicone product between the heat-generating electronic component and the IHS. The thermally conductive second silicone composition comprises I) a second shrink additive and II) a thermally conductive curable polyorganosiloxane composition (a curable polyorganosiloxane composition including a high loading of a thermally conductive filler, i.e., a quantity sufficient to enhance conduction of heat through the second silicone composition). The second shrink additive may be the same as the first shrink additive. Alternatively, the second shrink additive may be different from the first shrink additive. The step of interposing the second silicone composition between a heat-generating electronic component and the IHS can be performed before steps 2) and 3) in the method described above so that the first shrink additive may be removed from the first silicone composition and the second shrink additive may be removed from the thermally conductive second silicone composition without additional method steps. The first and second silicone compositions may be the same, alternatively different.

The silicone composition (independently used for both the first silicone composition and the second silicone composition) in the method of fabricating the electronic device independently comprises:
I) a shrink additive, and
II) a curable polyorganosiloxane composition. For convenience the descriptors “first” and/or “second” may be omitted herein when generally referring to elements or limitations having such descriptors such as, e.g., the silicone composition, the shrink additive, the curable polyorganosiloxane composition, the cured silicone product, iso-alkane, filler, heat-generating electronic component, thermal interface material, and the like. Such descriptors may be read as having first or second, alternatively first, alternatively second, alternatively first and second as modifiers therebefore, hereinafter “first and/or second.”

The shrink additive is a compound that is soluble in, but does not react with, the curable polyorganosiloxane composition. The shrink additive is present in the silicone composition before curing the curable polyorganosiloxane composition thereof. A portion of the shrink additive can be removed before and during cure of the curable polyorganosiloxane composition. However, most (e.g., more than 50%, alternatively 50% to 99.9%, and alternatively 66% to 99%) of the shrink additive should be removed after cure of the curable polyorganosiloxane composition so that the BLT of the cured silicone product shrinks, as compared to the BLT of the silicone composition interposed between the IHS and the substrate during step 1) of the method described herein, to provide the benefit of providing compressive force between the IHS and the electronic component. Curing the first curable polyorganosiloxane composition of the first silicone composition produces a first cured silicone product and curing the second curable polyorganosiloxane composition of the second silicone composition, if any, produces a second cured silicone product. Each of the first and second cured silicone products independently may be thermally conductive. The first and second cured silicone products may be the same, alternatively different. The shrink additive is capable of being removed during and/or after curing of the curable polyorganosiloxane composition without causing substantial voiding of the cured silicone product under the curing conditions. Each shrink additive independently may be removed both during and after curing of the curable polyorganosiloxane composition, alternatively entirely after curing of the curable polyorganosiloxane composition. “Voiding” generally refers to formation of gas pockets in the cured silicone product. Voiding may be measured using by viewing a cross sectional area of a cured product (adhesive) with a C-mode scanning acoustic microscope (CSAM). “Without substantial voiding” means that the amount of voiding may be no more than 10 vol %, alternatively no more than 5 vol %, alternatively, no more than 1 vol %, alternatively 0 vol % to 10 vol %, alternatively 0 vol % to 5 vol %, and alternatively 5 vol % to 10 vol % based on volume of the cured silicone product.

The shrink additive may be an organic solvent having a boiling point of 180° C. to 295° C., alternatively 210° C. to 265° C. The organic solvent may be a branched alkane, an ether, an ester, or a combination thereof. The branched alkane may be an iso-alkane of at least 10 carbon atoms. The iso-alkane may have at most 40 carbon atoms. Alternatively, the iso-alkane may have 10 to 16 carbon atoms. Alternatively, a combination of iso-alkanes may be used, such as a first iso-alkane of 10 to 13 carbon atoms and a second iso-alkane of 13 to 16 carbon atoms. Examples of such iso-alkanes are commercially available. For example, the mixture sold as IP Mixture 2028 from Idemitsu Kosan Co., Ltd. of Tokyo, Japan and the isoparaffinic fluids sold as Isopar™ C and Isopar™ E from Exxon Mobil Chemical of Houston, Tex., are suitable for use as the shrink additive in the curable polyorganosiloxane composition (a curable adhesive composition). If the boiling point or boiling point range of the shrink additive is too low to stay in the silicone composition until the curing step, it will be lost from the silicone composition before the curing step and thus may not cause sufficient shrinkage of the bondline thickness to provide the desired compressive force. If the boiling point is too high to allow the shrink additive to evaporate during the method, the shrink additive may remain in the curable polyorganosiloxane composition and not be lost due to evaporation during the method. The appropriate shrink additive can be chosen based on various factors including the evaporation rate of the solvent, the curing temperature of the curable polyorganosiloxane composition, the curing conditions selected in step 2), and the geometry of the application (e.g., the geometries of the electronic component, IHS, and heat sink selected).

The amount of shrink additive in the silicone composition depends on various factors including the properties of the shrink additive, such as boiling point; whether the curable polyorganosiloxane composition contains a high loading of thermally conductive filler, i.e., a quantity sufficient to enhance conduction of heat through the second silicone composition; and the conditions used in steps 2) and 3) in the method, such as temperature and pressure, however, the amount of shrink additive may range from 10 vol % to 40 vol % of the silicone composition, alternatively 15 vol % to 25 vol % of the silicone composition; with the balance of the silicone composition being the curable polyorganosiloxane composition.

The curable polyorganosiloxane composition includes:

(A) a catalyst, and
(B) an aliphatically unsaturated polyorganosiloxane having an average, per molecule, of one or more aliphatically unsaturated organic groups capable of undergoing a curing reaction. When ingredient (B) does not contain a silicon-bonded hydrogen atom, then the curable polyorganosiloxane composition further comprises ingredient (C), an SiH functional compound having an average, per molecule, of one or more silicon-bonded hydrogen atoms, which is distinct from ingredients (A) and (B). When the curable polyorganosiloxane composition further comprises a relatively high loading of a thermally conductive filler, i.e., a quantity sufficient to enhance conduction of heat through the second silicone composition, then this forms the thermally conductive curable polyorganosiloxane composition described above.

When the curable polyorganosiloxane composition is hydrosilylation reaction curable, ingredient (A) is a hydrosilylation reaction catalyst. Hydrosilylation reaction catalysts are commercially available. The hydrosilylation reaction catalyst for ingredient (A) can be a metal selected from platinum, rhodium, ruthenium, palladium, osmium, and iridium. Alternatively, the hydrosilylation reaction catalyst may be a compound of such a metal, for example, chloroplatinic acid, chloroplatinic acid hexahydrate, platinum dichloride, and complexes of said compounds with low molecular weight (e.g., 500 to 2,000 g/mol) polyorganosiloxanes or platinum compounds microencapsulated in a matrix or core/shell type structure. Complexes of platinum with low molecular weight polyorganosiloxanes include 1,3-diethenyl-1,1,3,3-tetramethyldisiloxane complexes with platinum. These complexes may be microencapsulated in a resin matrix. Exemplary hydrosilylation catalysts are described in U.S. Pat. Nos. 3,159,601; 3,220,972; 3,296,291; 3,419,593; 3,516,946; 3,814,730; 3,989,668; 4,784,879; 5,036,117; and 5,175,325 and EP 0 347 895 B. Microencapsulated hydrosilylation catalysts and methods of preparing them are known in the art, as exemplified in U.S. Pat. Nos. 4,766,176 and 5,017,654. The amount hydrosilylation reaction catalyst is sufficient to cure the hydrosilylation reaction curable silicone polyorganosiloxane composition (a curable adhesive composition). The exact amount of hydrosilylation reaction catalyst depends on various factors including the reactivities of ingredient (B) and any other ingredients in the curable polyorganosiloxane composition, the selection of hydrosilylation reaction catalyst and the curing conditions, such as temperature, selected in the method. However, the amount of hydrosilylation reaction catalyst may be sufficient to provide 1 ppm to 1,000 ppm of platinum group metal, based on the combined weights of all ingredients in the curable polyorganosiloxane composition.

Ingredient (B) is an aliphatically unsaturated polyorganosiloxane having an average, per molecule, of two or more aliphatically unsaturated organic groups capable of undergoing a curing reaction. Ingredient (B) may have a linear, branched, cyclic, or resinous structure having aliphatic unsaturation. Alternatively, ingredient (B) may have a linear and/or branched structure. Alternatively, ingredient (B) may have a resinous structure. Ingredient (B) may be a homopolymer or a copolymer. Ingredient (B) may be one polyorganosiloxane. Alternatively, ingredient (B) may comprise two or more polyorganosiloxanes differing in at least one of the following properties: structure, viscosity, average molecular weight, siloxane units, and sequence. The aliphatically unsaturated organic groups in ingredient (B) may be located at terminal, pendant, or both terminal and pendant positions.

The remaining silicon-bonded organic groups in ingredient (B) may be monovalent organic groups free of aliphatic unsaturation. Examples of monovalent hydrocarbon groups include, but are not limited to, alkyl such as Me, Et, Pr, Bu, pentyl, hexyl, heptyl, octyl, decyl, undecyl, dodecyl, and octadecyl; cycloalkyl such as cyclopentyl and cyclohexyl; aryl such as Ph, and naphthyl; and aralkyl such as tolyl, xylyl, benzyl, 1-phenylethyl and 2-phenylethyl. Examples of monovalent halogenated hydrocarbon groups include, but are not limited to, chlorinated alkyl groups such as chloromethyl and chloropropyl groups; fluorinated alkyl groups such as fluoromethyl, 2-fluoropropyl, 3,3,3-trifluoropropyl, 4,4,4-trifluorobutyl, 4,4,4,3,3-pentafluorobutyl, 5,5,5,4,4,3,3-heptafluoropentyl, 6,6,6,5,5,4,4,3,3-nonafluorohexyl, and 8,8,8,7,7-pentafluorooctyl; chlorinated cycloalkyl groups such as 2,2-dichlorocyclopropyl, 2,3-dichlorocyclopentyl; and fluorinated cycloalkyl groups such as 2,2-difluorocyclopropyl, 2,3-difluorocyclobutyl, 3,4-difluorocyclohexyl, and 3,4-difluoro-5-methylcycloheptyl. Examples of other monovalent organic groups include, but are not limited to, oxygen containing organic groups such as epoxy containing organic groups, e.g., glycidoxyalkyl, and nitrogen containing organic groups such as aminoalkyl and cyano-functional groups such as cyanoethyl and cyanopropyl.

Ingredient (B) may comprise a polydiorganosiloxane of

R¹₂R²SiO(R¹₂SiO)ₐ(R¹R²SiO)_{b}SiR¹₂R², Formula (I):

R¹₃SiO(R¹₂SiO)_{c}(R¹R²SiO)_{d}SiR¹₃, Formula (II):

or a combination thereof.

In formulae (I) and (II), each R¹ is independently a hydrogen atom or a monovalent organic group free of aliphatic unsaturation and each R² is independently an aliphatically unsaturated organic group, exemplified by those described above. Subscript a may be 0 or a positive number. Alternatively, subscript a has an average value of at least 2. The subscript a may have an average value of at most 5,000. Alternatively subscript a may have an average value ranging from 2 to 2000. Subscript b may be 0 or a positive number. The subscript b may have an average value of at most 5,000. Alternatively, subscript b may have an average value ranging from 0 to 2000. Subscript c may be 0 or a positive number. The subscript c may have an average value of at most 5,000. Alternatively, subscript c may have an average value ranging from 0 to 2000. Subscript d has an average value of at least 2. The subscript d may have an average value of at most 5,000. Alternatively subscript d may have an average value ranging from 2 to 2000. Suitable monovalent organic groups for R¹ are as described above for ingredient (B). Alternatively, each R¹ is a monovalent hydrocarbon group exemplified by alkyl such as Me and aryl such as Ph. Each R² is independently an aliphatically unsaturated monovalent organic group as described above for ingredient (B). Alternatively, R² is exemplified by alkenyl groups such as vinyl, allyl, butenyl, and hexenyl; and alkynyl groups such as ethynyl and propynyl.

Ingredient (B) may comprise a polydiorganosiloxane such as i) dimethylvinylsiloxy-terminated polydimethylsiloxane, ii) dimethylvinylsiloxy-terminated poly(dimethylsiloxane/methylvinylsiloxane), iii) dimethylvinylsiloxy-terminated polymethylvinylsiloxane, iv) trimethylsiloxy-terminated poly(dimethylsiloxane/methylvinylsiloxane), v) trimethylsiloxy-terminated polymethylvinylsiloxane, vi) dimethylvinylsiloxy-terminated poly(dimethylsiloxane/methylvinylsiloxane), vii) dimethylvinylsiloxy-terminated poly(dimethylsiloxane/methylphenylsiloxane), viii) dimethylvinylsiloxy-terminated poly(dimethylsiloxane/diphenylsiloxane), ix) phenyl,methyl,vinyl-siloxy-terminated polydimethylsiloxane, x) dimethylhexenylsiloxy-terminated polydimethylsiloxane, xi) dimethylhexenylsiloxy-terminated poly(dimethylsiloxane/m ethylhexenylsiloxane), xii) dimethylhexenylsiloxy-terminated polymethylhexenylsiloxane, xiii) trim ethylsiloxy-terminated poly(dimethylsiloxane/methylhexenylsiloxane), xiv) trimethylsiloxy-terminated polymethylhexenylsiloxane, xv) dimethylhexenyl-siloxy terminated poly(dimethylsiloxane/methylhexenylsiloxane), xvi) dimethylvinylsiloxy-terminated poly(dimethylsiloxane/methylhexenylsiloxane), or xvii) a combination thereof.

Methods of preparing polydiorganosiloxane fluids suitable for use as ingredient (B), such as hydrolysis and condensation of the corresponding organohalosilanes or equilibration of cyclic polydiorganosiloxanes, are known in the art.

In addition to, or instead of, the polydiorganosiloxane described above, ingredient (B) may comprise a resin such as an MQ resin containing R³₃SiO_{1/2} units (M-units) and SiO_{4/2} units (Q-units), a TD resin consisting essentially of R³SiO_{3/2} units (T-units) and R³₂SiO_{2/2} units (D-units), an MT resin consisting essentially of R³₃SiO_{1/2} units and R³SiO_{3/2} units, an MTD resin containing of R³₃SiO_{1/2} units, R³SiO_{3/2} units, and R³₂SiO_{2/2} units, or a combination thereof. An MQ resin contains, alternatively consists essentially of, alternatively consists of M and Q units; a TD resin T and D units; an MT resin M and T units; and an MTD resin M, T and D units.

Each R³ is a monovalent organic group exemplified by those described above for ingredient (B). Alternatively, the monovalent organic groups represented by R³ may have 1 to 20 carbon atoms. Alternatively, examples of monovalent organic groups for R³ include, but are not limited to, monovalent hydrocarbon groups and monovalent halogenated hydrocarbon groups.

The resin may contain an average of 3 to 30 mole percent of aliphatically unsaturated organic groups, alternatively 0.1 to 30 mole percent, alternatively 0.1 to 5 mole percent. The aliphatically unsaturated organic groups may be alkenyl groups, alkynyl groups, or a combination thereof. The mole percent of aliphatically unsaturated organic groups in the resin is the ratio of the number of moles of unsaturated group-containing siloxane units in the resin to the total number of moles of siloxane units in the resin, multiplied by 100.

Methods of preparing resins are well known in the art. For example, a resin may be prepared by treating a resin copolymer produced by the silica hydrosol capping process of Daudt, et al. with at least an alkenyl-containing endblocking reagent. The method of Daudt et al., is disclosed in U.S. Pat. No. 2,676,182.

The method of Daudt, et al. involves reacting a silica hydrosol under acidic conditions with a hydrolyzable triorganosilane such as trimethylchlorosilane, a siloxane such as hexamethyldisiloxane, or mixtures thereof, and recovering a copolymer having M-units and Q-units. The resulting copolymers generally contain from 2% to 5% by weight of hydroxyl groups.

The resin, which may contain less than 2% of silicon-bonded hydroxyl groups, may be prepared by reacting the product of Daudt, et al. with an unsaturated organic group-containing endblocking agent and an endblocking agent free of aliphatic unsaturation, in an amount sufficient to provide from 3 to 30 mole percent of unsaturated organic groups in the final product. Examples of endblocking agents include, but are not limited to, silazanes, siloxanes, and silanes. Suitable endblocking agents are known in the art and exemplified in U.S. Pat. Nos. 4,584,355; 4,591,622; and 4,585,836. A single endblocking agent or a mixture of such agents may be used to prepare the resin.

The amount of ingredient (B) in the curable polyorganosiloxane composition depends on various factors including the desired form of the cured silicone product of the composition, the quantity and reactivity of the aliphatically unsaturated groups of ingredient (B), the type and amount of ingredient (A), and the content of silicon-bonded hydrogen atoms of, ingredient (B) and/or ingredient (C), when present. However, the amount of ingredient (B) may range from 0.1% to 99.9% based on the weight of all ingredients in the curable polyorganosiloxane composition.

Ingredient (C) in the curable polyorganosiloxane composition is a SiH functional compound, i.e., a compound having an average, per molecule, of 2 or more silicon-bonded hydrogen atoms. Ingredient (C) may comprise a silane and/or an organohydrogensilicon compound. Alternatively, ingredient (C) may have an average, per molecule, of at least two silicon-bonded hydrogen atoms. Ingredient (C) may have an average per molecule of at most 10 silicon-bonded hydrogen atoms. The amount of ingredient (C) in the curable polyorganosiloxane composition depends on various factors including the SiH content of ingredient (C), the unsaturated group content of ingredient (B), and the properties of the cured silicone product of the composition desired, however, the amount of ingredient (C) may be sufficient to provide a molar ratio of SiH groups in ingredient (C) to aliphatically unsaturated organic groups in ingredient (B) (commonly referred to as the SiH:Vi ratio) ranging from 0.3:1 to 5:1, alternatively 0.5:1 to 3:1. Ingredient (C) can have a monomeric or polymeric (where polymeric includes two or more monomeric units) structure. When ingredient (C) has a polymeric structure, the polymeric structure may be linear, branched, cyclic, or resinous. When ingredient (C) is polymeric, then ingredient (C) can be a homopolymer or a copolymer. The silicon-bonded hydrogen atoms in ingredient (C) can be located at terminal, pendant, or at both terminal and pendant positions. Ingredient (C) may be one SiH functional compound. Alternatively, ingredient (C) may comprise a combination of two or more SiH functional compounds. Ingredient (C) may be two or more organohydrogenpolysiloxanes that differ in at least one of the following properties: structure, average molecular weight, viscosity, siloxane units, and sequence.

Ingredient (C) may comprise a silane of formula R⁴ₑSiH_{f}, where subscript e is 0, 1, 2, or 3; subscript f is 1, 2, 3, or 4, with the proviso that a quantity (e+f)=4. Each R⁴ is independently a halogen atom or a monovalent organic group. Suitable halogen atoms for R⁴ are exemplified by CI, F, Br, and I; alternatively Cl. Suitable monovalent organic groups for R⁴ include, but are not limited to, monovalent hydrocarbon and monovalent halogenated hydrocarbon groups. Monovalent hydrocarbon groups include, but are not limited to, alkyl such as Me, Et, Pr, Bu, pentyl, hexyl, heptyl, octyl, decyl, undecyl, dodecyl, and octadecyl; cycloalkyl such as cyclopentyl and cyclohexyl; aryl such as Ph and naphthyl; and aralkyl such as tolyl, xylyl, benzyl, 1-phenylethyl and 2-phenylethyl. Examples of monovalent halogenated hydrocarbon groups include, but are not limited to, chlorinated alkyl groups such as chloromethyl and chloropropyl groups; fluorinated alkyl groups such as fluoromethyl, 2-fluoropropyl, 3,3,3-trifluoropropyl, 4,4,4-trifluorobutyl, 4,4,4,3,3-pentafluorobutyl, 5,5,5,4,4,3,3-heptafluoropentyl, 6,6,6,5,5,4,4,3,3-nonafluorohexyl, and 8,8,8,7,7-pentafluorooctyl; chlorinated cycloalkyl groups such as 2,2-dichlorocyclopropyl, 2,3-dichlorocyclopentyl; and fluorinated cycloalkyl groups such as 2,2-difluorocyclopropyl, 2,3-difluorocyclobutyl, 3,4-difluorocyclohexyl, and 3,4-difluoro-5-methylcycloheptyl. Examples of other monovalent organic groups include, but are not limited to, oxygen containing organic groups such as epoxy containing groups, e.g., glycidoxyalkyl, and alkoxy groups such as methoxy, ethoxy, propoxy, and butoxy; and nitrogen containing organic groups such as aminoalkyl and cyano-functional groups such as cyanoethyl and cyanopropyl. Examples of suitable silanes for ingredient (C) are exemplified by trichlorosilane (HSiCl₃), Me₂HSiCl, or MeHSi(OMe)₂.

Alternatively, the organohydrogensilicon compound of ingredient (C) may comprise a polyorganohydrogensiloxane comprising siloxane units including, but not limited to, HR⁵₂SiO_{1/2}, R⁵₃SiO_{1/2}, HR⁵SiO_{2/2}, R⁵₂SiO₂₁₂, R⁵SiO_{3/2}, HSiO_{3/2} and SiO_{4/2} units. In the preceding formulae, each R⁵ is independently selected from the monovalent organic groups free of aliphatic unsaturation described above for ingredient (B).

Ingredient (C) may comprise a polyorganohydrogensiloxane of

R⁵₃SiO(R⁵₂SiO)_{g}(R⁵HSiO)ₕSiR⁵₃, Formula (III):

R⁵₂HSiO(R⁵₂SiO)ᵢ(R⁵HSiO)ⱼSiR⁵₂H, or Formula (IV):

a combination thereof.

In formulae (III) and (IV) above, subscript g has an average value ranging from 0 to 2000, subscript h has an average value ranging from 2 to 2000, subscript i has an average value ranging from 0 to 2000, and subscript j has an average value ranging from 0 to 2000. Each R⁵ is independently a monovalent organic group, as described above.

Polyorganohydrogensiloxanes for ingredient (C) are exemplified by: a) dimethylhydrogensiloxy-terminated polydimethylsiloxane, b) dimethylhydrogensiloxy-terminated poly(dimethylsiloxane/methylhydrogensiloxane), c) dimethylhydrogensiloxy-terminated polymethylhydrogensiloxane, d) trim ethylsiloxy-terminated poly(dimethylsiloxane/methylhydrogensiloxane), e) trim ethylsiloxy-terminated polymethylhydrogensiloxane, f) a resin consisting essentially of H(CH₃)₂SiO_{1/2} units and SiO_{4/2} units, and g) a combination thereof.

Methods of preparing linear, branched, and cyclic organohydrogenpolysiloxanes suitable for use as ingredient (C), such as hydrolysis and condensation of organohalosilanes, are known in the art. Methods of preparing organohydrogenpolysiloxane resins suitable for use as ingredient (C) are also well known as exemplified in U.S. Pat. Nos. 5,310,843; 4,370,358; and 4,707,531.

Alternatively, the organohydrogensilicon compound of ingredient (C) may comprise a compound of formula (V):

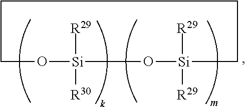

where each R²⁹ is independently selected from a hydrogen atom and a monovalent organic group comprising 1 to 20 member atoms, e.g., member atoms include carbon atoms and may include heteroatoms such as N and O, subscript k is an integer with a value ranging from 0 to 18, subscript m is an integer with a value ranging from 0 to 19, a quantity (k+m) is an integer from 3 to 20, alternatively 3 to 40. Each R³⁰ is independently selected from a monovalent organic group, a halogen atom, and a siloxane unit, such as those described above for the resins of ingredient (B). Alternatively each R³⁰ is a functional group independently selected from a halogen atom, an ether group, an alkoxy group, an alkoxyether group, an acyl group, an epoxy group, an amino group, a silyl group, or a group of formula —Z—R³¹, where each Z is independently selected from an oxygen atom and a divalent hydrocarbon group comprising 2 to 20 carbon atoms, each R³¹ group is independently selected from —BR²⁹ᵤR³²₂₋ᵤ, —Si R²⁹ᵥR³²₃₋ᵥ, or a group described by formula (VI): (R³²₃₋ₙR²⁹ₙSiO_{1/2})_{w} (R³²₂₋ₒR²⁹ₒSO_{2/2})ₓ (R³²₁₋ₚR²⁹ₚSiO_{3/2})_{y} (SiO_{4/2})_{z} (CR²⁹_{q}R³²_{1-q})ₐₐ (CR²⁹ᵣR³²₂₋ᵣ)_{bb} (O(CR²⁹ₛR³²₂₋ₛ)_{cc} (CR²⁹ₜR³²₃₋ₜ)_{dd} where B refers to boron, each R²⁹ is as described above, a quantity (w+x+y+z+aa+bb+cc+dd) is at least 2, subscript n is an integer from 0 to 3, subscript o is an integer from 0 to 2, subscript p is an integer from 0 to 1, subscript q is an integer from 0 to 1, subscript r is an integer from 0 to 2, subscript s is an integer from 0 to 2, subscript t is an integer from 0 to 3, subscript u is an integer from 0 to 2, subscript v is an integer from 0 to 3, each R³² is a substituent independently selected from a halogen atom, an ether group, an alkoxy group, an alkoxyether group, an acyl group, an epoxy group, an amino group, a silyl group, or a Z-G group, where Z is as described above, each G is a cyclosiloxane described by formula (VII):

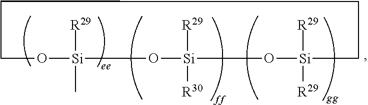

where R²⁹ and R³⁰ are as described above, subscript ee is 1, subscript ff is an integer from 0 to 18, subscript gg is an integer from 0 to 18, a quantity (ff+gg) is an integer from 2 to 20, provided in formula (VII) that one of the R³² groups is replaced by the Z group bonding the R³¹ group to the cyclosiloxane of formula (VII), and provided further if a quantity (aa+bb+cc+dd)>0 then a quantity (w+x+y+z)>0. Unlike in cyclobutane structures, in the foregoing cyclosiloxane structures the square corners do not represent CH₂ groups.

Such organohydrogensilicon compounds are commercially available and include, SYL-OFF® SL2 CROSSLINKER and SYL-OFF® SL12 CROSSLINKER, both of which are commercially available from Dow Corning Corporation of Midland, Mich., U.S.A. The organohydrogensilicon compounds described above and methods for their preparation are exemplified in WO2003/093349 and WO2003/093369. An exemplary organohydrogensilicon compound may have the general formula:

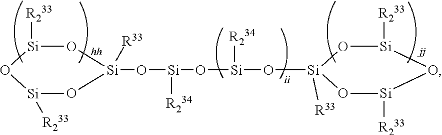

where each R³³ is independently selected from a hydrogen atom and a monovalent organic group; each R³⁴ is independently selected from a hydrogen atom, a monovalent organic group, and a group of formula

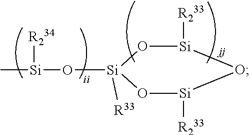

subscript hh is an integer of at least 1; subscript jj is an integer of at least 1; and subscript ii is an integer with a minimum value of 0. In the general formula, at least one instance of R³³ is a hydrogen atom. Suitable monovalent organic groups for R³³ and/or R³⁴ are exemplified by those groups described above for R²⁹.

The exact amount of ingredient (C) in the curable polyorganosiloxane composition depends on various factors including reactivity of ingredient (A), the type and amount of ingredient (B), whether ingredient (B) contains a silicon-bonded hydrogen atom, and the type and amount of any additional ingredient (other than ingredient (C)), if present. However, the amount of ingredient (C) in the curable polyorganosiloxane composition may range from 0% to 25%, alternatively 0.1% to 15%, and alternatively 1% to 5%, based on total weight of all ingredients in the curable polyorganosiloxane composition.

Alternatively, when the curable polyorganosiloxane composition is peroxide curable, then ingredient (A) may be a peroxide catalyst. The amount of peroxide catalyst added to the peroxide curable polyorganosiloxane composition depends on the specific peroxide compound selected, however, the amount may range from 0.2 to 5 parts (by weight), per 100 parts by weight of ingredient (B). Examples of peroxide compounds suitable for use as the catalyst include, but are not limited to, 2,4-dichlorobenzoyl peroxide, dicumyl peroxide, and a combination thereof; as well as combinations of such a peroxide with a benzoate compound such as tertiary-butyl perbenzoate.

Ingredient (B) of the peroxide curable polyorganosiloxane composition is a polydiorganosiloxane having an average of at least two aliphatically unsaturated organic groups per molecule, such as the polydiorganosiloxane described above as ingredient (B) of the hydrosilylation reaction curable polyorganosiloxane composition. Ingredient (B) may have an average of at most 10 aliphatically unsaturated organic groups per molecule.

Ingredient (C) of the peroxide curable silicone polyorganosiloxane composition (a curable adhesive composition) is a crosslinker, which may optionally be added to the peroxide curable polyorganosiloxane composition to improve (reduce) compression set of the cured silicone product prepared by curing this curable polyorganosiloxane composition. The amount of ingredient (C) in the peroxide curable polyorganosiloxane composition depends on various factors including the SiH content of ingredient (C), the unsaturated group content of ingredient (B), and the properties of the cured silicone product desired, however, the amount of ingredient (C) may be sufficient to provide a molar ratio of SiH groups in ingredient (C) to aliphatically unsaturated organic groups in ingredient (B) (commonly referred to as the SiH:Vi ratio) ranging from 0.3:1 to 5:1. The amount of ingredient (C) in the peroxide curable polyorganosiloxane composition may range from 0 to 15 parts (by weight) per 100 parts by weight of ingredient (B). Ingredient (C) may comprise a polydiorganohydrogensiloxane having an average of at least two silicon-bonded hydrogen atoms per molecule. The polydiorganohydrogensiloxane may have an average of at most 10 silicon-bonded hydrogen atoms per molecule. Ingredient (C) in the peroxide curable polyorganosiloxane composition is exemplified by the polydiorganohydrogensiloxanes described as ingredient (C) in the hydrosilylation curable polyorganosiloxane composition.

The curable polyorganosiloxane composition may optionally further comprise one or more additional ingredients, which are distinct from ingredient (A), ingredient (B), and optional ingredient (C) described above. Suitable additional ingredients are exemplified by (D) a spacer, (E) a filler, (F) a filler-treating agent, (G) a stabilizer, (H) an adhesion promoter, (J) a flux agent, (K) an anti-aging additive, (L) a pigment, and a combination thereof.

Ingredient (D) is a spacer. Spacers may comprise organic particles, inorganic particles, or a combination thereof. Spacers may be thermally conductive, electrically conductive, or both. Spacers may have a desired particle size, for example, particle size may range from 25 micrometers (μm) to 125 μm. Spacers may comprise monodisperse beads, such as glass or polymer (e.g., polystyrene) beads. Spacers may comprise thermally conductive fillers such as alumina, aluminum nitride, atomized metal powders, boron nitride, and copper. The amount of ingredient (D) depends on various factors including the particle size distribution, pressure to be applied during use of the curable polyorganosiloxane composition or the cured silicone product prepared therefrom, temperature during use, and desired thickness of the curable polyorganosiloxane composition or the cured silicone product prepared therefrom. However, the curable polyorganosiloxane composition may contain an amount of ingredient (D) ranging from 0.05% to 2%, alternatively 0.1% to 1%.

Ingredient (E) is a filler. The filler may comprise a reinforcing filler, an extending filler, a conductive filler, or a combination thereof. For example, the curable polyorganosiloxane composition may optionally further comprise ingredient (E1), a reinforcing filler, which when present may be added in an amount ranging from 0.1% to 95%, alternatively 1% to 60%, based on the weight of all ingredients in the curable polyorganosiloxane composition. The exact amount of ingredient (E1) depends on various factors including the form of the cured silicone product of the composition (e.g., gel or rubber) and whether any other fillers are added. Examples of suitable reinforcing fillers include chopped fiber such as chopped KEVLAR®, and/or reinforcing silica fillers such as fumed silica, silica aerogel, silica xerogel, and precipitated silica. Fumed silicas are known in the art and commercially available; e.g., fumed silica sold under the name CAB-O-SIL® by Cabot Corporation of Boston, Mass., U.S.A.

The curable polyorganosiloxane composition may optionally further comprise ingredient (E2) an extending filler in an amount ranging from 0.1% to 95%, alternatively 1 to 60%, and alternatively 1% to 20%, based on the weight of all ingredients in the curable polyorganosiloxane composition. Examples of extending fillers include crushed quartz, aluminum oxide, magnesium oxide, calcium carbonate such as precipitated calcium carbonate, zinc oxide, talc, diatomaceous earth, iron oxide, clays, mica, titanium dioxide, zirconia, sand, carbon black, graphite, or a combination thereof. Extending fillers are known in the art and commercially available, such as a ground silica sold under the name MIN-U-SIL® by U.S. Silica of Berkeley Springs, W. Va., U.S.A. Suitable precipitated calcium carbonates included Winnofil® SPM from Solvay Chemicals of Brussels, Belgium, and ULTRA-PFLEX® and ULTRA-PFLEX® 100 from Specialty Minerals Inc., Bethlehem, Pa., U.S.A.

The composition may optionally further comprise ingredient (E3) a conductive filler. Ingredient (E3) may be both thermally conductive and electrically conductive. Alternatively, ingredient (E3) may be thermally conductive and electrically insulating. Ingredient (E3) may be selected from the group consisting of aluminum nitride, aluminum oxide, aluminum trihydrate, barium titanate, beryllium oxide, boron nitride, carbon fibers, diamond, graphite, magnesium hydroxide, magnesium oxide, metal particulate, onyx, silicon carbide, tungsten carbide, zinc oxide, and a combination thereof. Ingredient (E3) may comprise a metallic filler, an inorganic filler, a meltable filler, or a combination thereof. Metallic fillers include particles of metals and particles of metals having layers on the surfaces of the particles. These layers may be, for example, metal nitride layers or metal oxide layers on the surfaces of the particles. Suitable metallic fillers are exemplified by particles of metals selected from the group consisting of aluminum, copper, gold, nickel, and combinations thereof, and alternatively aluminum. Suitable metallic fillers are further exemplified by particles of the metals listed above having layers on their surfaces selected from the group consisting of aluminum nitride, aluminum oxide, copper oxide, nickel oxide, silver oxide, and combinations thereof. For example, the metallic filler may comprise aluminum particles having aluminum oxide layers on their surfaces.

Inorganic conductive fillers are exemplified by onyx; aluminum trihydrate, metal oxides such as aluminum oxide, beryllium oxide, magnesium oxide, and zinc oxide; nitrides such as aluminum nitride and boron nitride; carbides such as silicon carbide and tungsten carbide; and combinations thereof. Alternatively, inorganic conductive fillers are exemplified by aluminum oxide, zinc oxide, and combinations thereof.

Meltable fillers may comprise Bi, Ga, In, Sn, or an alloy thereof. The meltable filler may optionally further comprise Ag, Au, Cd, Cu, Pb, Sb, Zn, or a combination thereof. Examples of suitable meltable fillers include Ga, In—Bi—Sn alloys, Sn—In—Zn alloys, Sn—In—Ag alloys, Sn—Ag—Bi alloys, Sn—Bi—Cu—Ag alloys, Sn—Ag—Cu—Sb alloys, Sn—Ag—Cu alloys, Sn—Ag alloys, Sn—Ag—Cu—Zn alloys, and combinations thereof. The meltable filler may have a melting point ranging from 50° C. to 250° C., alternativelyl 50° C. to 225° C. The meltable filler may be a eutectic alloy, a non-eutectic alloy, or a pure metal.

Fillers are commercially available. For example, meltable fillers may be obtained from Indium Corporation of America, Utica, N.Y., U.S.A.; Arconium, Providence, R.I., U.S.A.; and AIM Solder, Cranston, R.I., U.S.A. Aluminum fillers are commercially available, for example, from Toyal America, Inc. of Naperville, Ill., U.S.A. and Valimet Inc., of Stockton, Calif., U.S.A. Other thermally conductive fillers are also commercially available. For example, CB-A20S and AI-43-Me are aluminum oxide fillers of differing particle sizes commercially available from Showa-Denko, and AA-04, AA-2, and AA18 are aluminum oxide fillers commercially available from Sumitomo Chemical Company. Zinc oxides, such as zinc oxides having trademarks KADOX® and XX®, are commercially available from Zinc Corporation of America of Monaca, Pa., U.S.A.

The shape of the filler particles is not specifically restricted, however, rounded or spherical particles may prevent viscosity increase to an undesirable level upon high loading of the filler in the curable polyorganosiloxane composition.

Ingredient (E) may be a single filler or a combination of two or more fillers that differ in at least one property such as particle shape, average particle size, particle size distribution, and type of filler. For example, it may be desirable to use a combination of fillers, such as a first filler having a larger average particle size and a second filler having a smaller average particle size. Use of a first filler having a larger average particle size and a second filler having a smaller average particle size than the first filler may improve packing efficiency and/or may reduce viscosity of the composition as compared to a composition without such a combination of fillers. And, when the filler is thermally conductive, the combination may enhance heat transfer.

The average particle size of the filler will depend on various factors including the type of the filler selected for ingredient (E) and the exact amount added to the composition, as well as the end use for the reaction product of the composition. However, the filler may have an average particle size ranging from 0.1 micrometer (μm) to 80 μm, alternatively 0.1 μm to 50 μm, and alternatively 0.1 μm to 10 μm.

The amount of ingredient (E) in the curable polyorganosiloxane composition depends on various factors including the end use selected for the curable polyorganosiloxane composition and the cured silicone product, the type and amount of ingredient (B), and the type and amount of the filler selected for ingredient (E). However, the amount of ingredient (E) may range from 0 vol % to 80 vol %, alternatively 50 vol % to 75 vol %, and alternatively 30 vol % to 80 vol % of the curable polyorganosiloxane composition.

The curable polyorganosiloxane composition may optionally further comprise ingredient (F) a filler-treating agent. The amount of ingredient (F) will vary depending on factors such as the type of filler-treating agent selected and the type and amount of particulates (such as ingredients (E) and/or (D)) to be treated, and whether the particulates are treated before being added to the curable polyorganosiloxane composition, or whether the particulates are treated in situ. However, ingredient (F) may be used in an amount ranging from 0.01% to 20%, alternatively 0.1% to 15%, and alternatively 0.5% to 5%, based on the weight of all ingredients in the composition. Particulates, such as the filler, the spacer, and/or certain pigments, when present, may optionally be surface treated with ingredient (F). Particulates may be treated with ingredient (F) before being added to the composition, or in situ. Ingredient (F) may comprise an alkoxysilane, an alkoxy-functional oligosiloxane, a cyclic polyorganosiloxane, a hydroxyl-functional oligosiloxane such as a dimethyl siloxane or methyl phenyl siloxane, or a fatty acid or its salt. Examples of fatty acids or their salts include stearates such as calcium stearate.

Some representative organosilicon filler treating agents that can be used as ingredient (F) include compounds normally used to treat silica fillers such as organochlorosilanes, organosiloxanes, organodisilazanes such as hexaalkyl disilazane, and organoalkoxysilanes such as C₆H₁₃Si(OCH₃)₃, C₈H₁₇Si(OC₂H₅)₃, C₁₀H₂₁Si(OCH₃)₃, C₁₂H₂₅Si(OCH₃)₃, C₁₄H₂₉Si(OC₂H₅)₃, and C₆H₅CH₂CH₂Si(OCH₃)₃. Other filler-treating agents that can be used include alkylthiols, fatty acids and their salts, titanates, titanate coupling agents, zirconate coupling agents, and combinations thereof.

Alternatively, ingredient (F) may comprise an alkoxysilane having the formula: R¹¹ₘSi(OR¹²)₍₄₋ₘ₎, where subscript m may be an integer from 1 to 3, alternatively subscript m is 3. Each R¹¹ is independently a monovalent organic group, such as a monovalent hydrocarbon group of 1 to 50 carbon atoms, alternatively 8 to 30 carbon atoms, alternatively 8 to 18 carbon atoms. R¹¹ is exemplified by alkyl groups such as hexyl, octyl, dodecyl, tetradecyl, hexadecyl, and octadecyl; and aromatic groups such as benzyl and phenylethyl. R¹¹ may be saturated or unsaturated, and branched or unbranched. Alternatively, R¹¹ may be saturated and unbranched.

Each R¹² is independently a saturated hydrocarbon group of 1 to 4 carbon atoms, alternatively 1 to 2 carbon atoms. Alkoxysilanes suitable for use as ingredient (F) are exemplified by hexyltrimethoxysilane, octyltriethoxysilane, decyltrimethoxysilane, dodecyltrimethoxysilane, tetradecyltrimethoxysilane, phenylethyltrimethoxysilane, octadecyltrimethoxysilane, octadecyltriethoxysilane, and combinations thereof.

Alkoxy-functional oligosiloxanes may also be used as filler-treating agents. For example, suitable alkoxy-functional oligosiloxanes include those of the formula (V): (R¹³O)ₙSi(OSiR¹⁴₂R¹⁵)₍₄₋ₙ₎. In this formula, subscript n is 1, 2 or 3, alternatively subscript n is 3. Each R¹³ may be an alkyl group, for example, and alkyl group with 1 to 12 carbon atoms, alternatively 1 to 8 carbon atoms. Each R¹⁴ may be an unsaturated monovalent hydrocarbon group of 1 to 10 carbon atoms. Each R¹⁵ may be an unsaturated monovalent hydrocarbon group having at least 10 carbon atoms. The unsaturated monovalent hydrocarbon group may have at most 50 carbon atoms.

Certain particulates, such as metal fillers, may be treated with alkylthiols such as octadecyl mercaptan; fatty acids such as oleic acid and stearic acid; and a combination thereof.

Filler-treating agents for alumina or passivated aluminum nitride may include alkoxysilyl functional alkylmethyl polysiloxanes (e.g., partial hydrolysis condensate of R¹⁶ₒR¹⁷ₚ Si(OR¹⁸)₍₄₋ₒ₋ₚ₎ or cohydrolysis condensates or mixtures), or similar materials where the hydrolyzable group may comprise silazane, acyloxy or oximo. In all of these, a group tethered to Si, such as R¹⁶ in the formula above, is a long-chain unsaturated monovalent hydrocarbon or monovalent aromatic-functional hydrocarbon. Each R¹⁷ is independently a monovalent hydrocarbon group, and each R¹⁸ is independently a monovalent hydrocarbon group of 1 to 4 carbon atoms. In the formula above, subscript o is 1, 2, or 3 and subscript p is 0, 1, or 2, with the proviso that a quantity (o+p) is 1, 2, or 3.

Other filler-treating agents include alkenyl functional polyorganosiloxanes. Suitable alkenyl functional polyorganosiloxanes include, but are not limited to:

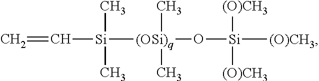

where subscript q has a value up to 1,500. Other filler-treating agents include mono-endcapped alkoxy functional polydiorganosiloxanes, i.e., polydiorganosiloxanes having an alkoxy group at one end. Such filler-treating agents are exemplified by the formula: R²⁵R²⁶₂SiO(R²⁶₂SiO)ᵤSi(OR²⁷)₃, where subscript u has a value of 0 to 100, alternatively 1 to 50, alternatively 1 to 10, and alternatively 3 to 6. Each R²⁵ is independently selected from an alkyl group, such as Me, Et, Pr, Bu, hexyl, and octyl; and an alkenyl group, such as vinyl, allyl, butenyl, and hexenyl. Each R²⁶ is independently an alkyl group such as Me, Et, Pr, Bu, hexyl, and octyl. Each R²⁷ is independently an alkyl group such as Me, Et, Pr, and Bu. Alternatively, each R²⁵, each R²⁶, and each R²⁷ is Me. Alternatively, each R²⁵ is Vi. Alternatively, each R²⁶ and each R²⁷ is Me.

Alternatively, a polyorganosiloxane capable of hydrogen bonding is useful as a filler-treating agent. This strategy to treating the surface of a filler takes advantage of multiple hydrogen bonds, either clustered or dispersed or both, as the means to tether the compatibilization moiety to the filler surface. The polyorganosiloxane capable of hydrogen bonding has an average, per molecule, of at least one silicon-bonded group capable of hydrogen bonding. The polyorganosiloxane capable of hydrogen bonding may have an average, per molecule, of at most ten silicon-bonded groups capable of hydrogen bonding. The group may be selected from: an organic group having multiple hydroxyl functionalities or an organic group having at least one amino functional group. The organic group may have at most 4 amino functional groups. The polyorganosiloxane capable of hydrogen bonding means that hydrogen bonding is the primary mode of attachment for the polyorganosiloxane to a filler. By primary mode, the hydrogen bonding of the polyorganosiloxane to the filler may be greater than 50 mole percent (mol %), alternatively >75 mol %, alternatively >90 mol %, alternatively 100 mol % of the bonding therebetween relative to total of hydrogen bonding plus covalent bonding. The polyorganosiloxane may be incapable of forming covalent bonds with the filler. The polyorganosiloxane capable of hydrogen bonding may be selected from the group consisting of a saccharide-siloxane polymer, an amino-functional polyorganosiloxane, and a combination thereof. Alternatively, the polyorganosiloxane capable of hydrogen bonding may be a saccharide-siloxane polymer. The amount of ingredient (F) depends on various factors including the type and amount of particulate ingredient(s) to be treated and the type of filler-treating agent selected. However, the amount of ingredient (F) may range from 0 to 5%, alternatively 0.1% to 3% based on the combined weights of all ingredients in the curable polyorganosiloxane composition.

Ingredient (G) is a stabilizer that may be used for altering the reaction rate of the curable polyorganosiloxane composition, as compared to a composition containing the same ingredients but with the stabilizer omitted. Stabilizers for hydrosilylation curable polyorganosiloxane compositions are exemplified by acetylenic alcohols such as 3,5-dimethyl-1-hexyn-3-ol, 1-butyn-3-ol, 1-propyn-3-ol, 3-methyl-1-butyn-3-ol, 3-methyl-1-pentyn-3-ol, 3-phenyl-1-butyn-3-ol, 4-ethyl-1-octyn-3-ol, and 1-ethynyl-1-cyclohexanol, and a combination thereof; cycloalkenylsiloxanes such as methylvinylcyclosiloxanes exemplified by 1,3,5,7-tetramethyl-1,3,5,7-tetravinylcyclotetrasiloxane, 1,3,5,7-tetramethyl-1,3,5,7-tetrahexenylcyclotetrasiloxane, and a combination thereof; ene-yne compounds such as 3-methyl-3-penten-1-yne, 3,5-dimethyl-3-hexen-1-yne; triazoles such as benzotriazole; phosphines; mercaptans; hydrazines; amines, such as tetramethyl ethylenediamine, dialkyl fumarates, dialkenyl fumarates, dialkoxyalkyl fumarates, maleates such as diallyl maleate; nitriles; ethers; carbon monoxide; alkenes such as cyclo-octadiene, divinyltetramethyldisiloxane; alcohols without acetylenic function such as benzyl alcohol; and a combination thereof.

Alternatively, ingredient (G) in the curable polyorganosiloxane composition may be a silylated acetylenic compound. Without wishing to be bound by theory, it is thought that adding a silylated acetylenic compound reduces yellowing of the cured silicone product prepared from hydrosilylation reaction of the curable polyorganosiloxane composition as compared to a reaction product from hydrosilylation of a composition that does not contain a silylated acetylenic compound or that contains an organic acetylenic alcohol stabilizer, such as those described above.

The silylated acetylenic compound is exemplified by (3-methyl-1-butyn-3-oxy)trimethylsilane, ((1,1-dimethyl-2-propynyl)oxy)trimethylsilane, bis(3-methyl-1-butyn-3-oxy)dimethylsilane, bis(3-methyl-1-butyn-3-oxy)silane, methylvinylsilane, bis((1,1-dimethyl-2-propynyl)oxy)dimethylsilane, methyl(tris(1,1-dimethyl-2-propynyloxy))silane, methyl(tris(3-methyl-1-butyn-3-oxy))silane, (3-methyl-1-butyn-3-oxy)dimethylphenylsilane, (3-methyl-1-butyn-3-oxy)dimethylhexenylsilane, (3-methyl-1-butyn-3-oxy)triethylsilane, bis(3-methyl-1-butyn-3-oxy)methyltrifluoropropylsilane, (3,5-dimethyl-1-hexyn-3-oxy)trimethylsilane, (3-phenyl-1-butyn-3-oxy)diphenylmethylsilane, (3-phenyl-1-butyn-3-oxy)dimethylphenylsilane, (3-phenyl-1-butyn-3-oxy)dimethylvinylsilane, (3-phenyl-1-butyn-3-oxy)dimethylhexenylsilane, (cyclohexyl-1-ethyn-1-oxy)dimethylhexenylsilane, (cyclohexyl-1-ethyn-1-oxy)dimethylvinylsilane, (cyclohexyl-1-ethyn-1-oxy)diphenylmethylsilane, (cyclohexyl-1-ethyn-1-oxy)trimethylsilane, and combinations thereof. Alternatively, ingredient (G) is exemplified by methyl(tris(1,1-dimethyl-2-propynyloxy))silane, ((1,1-dimethyl-2-propynyl)oxy)trimethylsilane, or a combination thereof. The silylated acetylenic compound useful as ingredient (G) may be prepared by methods known in the art, such as silylating an acetylenic alcohol described above by reacting it with a chlorosilane in the presence of an acid receptor.

The amount of stabilizer added to the curable polyorganosiloxane composition will depend on various factors including the desired pot life of the curable polyorganosiloxane composition, whether the curable polyorganosiloxane composition will be a one part composition or a multiple part composition, the particular stabilizer used, and the selection and amount of ingredient (C), if present. However, when present, the amount of stabilizer may range from 0% to 1%, alternatively 0% to 5%, alternatively 0.001% to 1%, alternatively 0.01% to 0.5%, and alternatively 0.0025% to 0.025%, based on the combined weight of all ingredients in the composition.

Ingredient (H) is an adhesion promoter. Suitable adhesion promoters for ingredient (H) may comprise a transition metal chelate, a hydrocarbonoxysilane such as an alkoxysilane, a combination of an alkoxysilane and a hydroxy-functional polyorganosiloxane, or a combination thereof. Adhesion promoters are known in the art and may comprise silanes having the formula R¹⁹ᵣR²⁰ₛSi(OR²¹)₄₋₍ᵣ₊ₛ) where each R¹⁹ is independently a monovalent organic group having at least 3 carbon atoms up to, for example, 8 carbon atoms; R²⁰ contains at least one SiC bonded substituent having an adhesion-promoting group, such as epoxy, mercapto or acrylate groups; subscript r has a value ranging from 0 to 2; subscript s is either 1 or 2; and the sum of (r+s) is not greater than 3. R²⁰ may contain at most four SiC bonded substituent having an adhesion-promoting group. Each R²¹ is independently a saturated hydrocarbon group. Saturated hydrocarbon groups for R²¹ may be, for example, an alkyl group of 1 to 4 carbon atoms, alternatively 1 to 2 carbon atoms. R²¹ is exemplified by methyl, ethyl, propyl, and butyl. Alternatively, the adhesion promoter may comprise a partial condensate of the above silane. Alternatively, the adhesion promoter may comprise a combination of an alkoxysilane and a hydroxy-functional polyorganosiloxane. Alternatively, the adhesion promoter may comprise 1,6-bis(trimethoxysilyl)hexane.

Alternatively, the adhesion promoter may comprise an unsaturated or epoxy-functional compound. The adhesion promoter may comprise an unsaturated or epoxy-functional alkoxysilane. For example, the functional alkoxysilane may have the formula R²²ₜSi(OR²³)₍₄₋ₜ₎, where subscript t is 1, 2, or 3, alternatively subscript t is 1. Each R²² is independently a monovalent organic group with the proviso that at least one R²² is an unsaturated organic group or an epoxy-functional organic group. Epoxy-functional organic groups for R²² are exemplified by 3-glycidoxypropyl and (epoxycyclohexyl)ethyl. Unsaturated organic groups for R²² are exemplified by 3-methacryloyloxypropyl, 3-acryloyloxypropyl, and unsaturated monovalent hydrocarbon groups such as vinyl, allyl, hexenyl, undecenyl. Each R²³ is independently a saturated hydrocarbon group of 1 to 4 carbon atoms, alternatively 1 to 2 carbon atoms. R²³ is exemplified by Me, Et, Pr, and Bu.

Examples of suitable epoxy-functional alkoxysilanes include 3-glycidoxypropyltrimethoxysilane, 3-glycidoxypropyltriethoxysilane, (epoxycyclohexyl)ethyldimethoxysilane, (epoxycyclohexyl)ethyldiethoxysilane and combinations thereof. Examples of suitable unsaturated alkoxysilanes include vinyltrimethoxysilane, allyltrimethoxysilane, allyltriethoxysilane, hexenyltrimethoxysilane, undecylenyltrimethoxysilane, 3-methacryloyloxypropyl trimethoxysilane, 3-methacryloyloxypropyl triethoxysilane, 3-acryloyloxypropyl trimethoxysilane, 3-acryloyloxypropyl triethoxysilane, and combinations thereof.

Alternatively, the adhesion promoter may comprise an epoxy-functional siloxane such as a reaction product of a hydroxy-terminated polyorganosiloxane with an epoxy-functional alkoxysilane, as described above, or a physical blend of the hydroxy-terminated polyorganosiloxane with the epoxy-functional alkoxysilane. The adhesion promoter may comprise a combination of an epoxy-functional alkoxysilane and an epoxy-functional siloxane. For example, the adhesion promoter is exemplified by a mixture of 3-glycidoxypropyltrimethoxysilane and a reaction product of hydroxy-terminated methylvinylsiloxane with 3-glycidoxypropyltrimethoxysilane, or a mixture of 3-glycidoxypropyltrimethoxysilane and a hydroxy-terminated methylvinylsiloxane, or a mixture of 3-glycidoxypropyltrimethoxysilane and a hydroxy-terminated methylvinyl/dimethylsiloxane copolymer.

Alternatively, the adhesion promoter may comprise a transition metal chelate. Suitable transition metal chelates include titanates, zirconates such as zirconium acetylacetonate, aluminum chelates such as aluminum acetylacetonate, and combinations thereof. Alternatively, the adhesion promoter may comprise a combination of a transition metal chelate with an alkoxysilane, such as a combination of glycidoxypropyltrimethoxysilane with an aluminum chelate or a zirconium chelate.

The exact amount of ingredient (H) depends on various factors including the type of adhesion promoter selected as ingredient (H) and the end use of the curable polyorganosiloxane composition and its cured silicone product. However, ingredient (H), when present, may be added to the curable polyorganosiloxane composition in an amount ranging from 0.01 to 50 weight parts based on the combined weight of all ingredients in the curable polyorganosiloxane composition, alternatively 0.01 to 10 weight parts, and alternatively 0.01 to 5 weight parts. Ingredient (H) may be one adhesion promoter. Alternatively, ingredient (H) may comprise two or more different adhesion promoters that differ in at least one of the following properties: structure, viscosity, average molecular weight, polymer units, and sequence.

Ingredient (J) is a flux agent. The curable polyorganosiloxane composition may comprise 0% to 2% of the flux agent based on the combined weight of all ingredients in the curable polyorganosiloxane composition. Molecules containing chemically active functional groups such as carboxylic acid and amines can be used as flux agents. Such flux agents can include aliphatic acids such as succinic acid, abietic acid, oleic acid, and adipic acid; aromatic acids such as benzoic acids; aliphatic amines and their derivatives, such as triethanolamine, hydrochloride salts of amines, and hydrobromide salts of amines. Flux agents are known in the art and are commercially available.

Ingredient (K) is an anti-aging additive. The anti-aging additive may comprise an antioxidant, an ultraviolet light (UV) absorber, a UV stabilizer, a heat stabilizer, or a combination thereof. Suitable antioxidants are known in the art and are commercially available. Suitable antioxidants include phenolic antioxidants and combinations of phenolic antioxidants with stabilizers. Phenolic antioxidants include fully sterically hindered phenols and partially hindered phenols; and sterically hindered amines such as tetramethyl-piperidine derivatives. Suitable phenolic antioxidants include vitamin E and IRGANOX® 1010 from Ciba Specialty Chemicals, U.S.A. IRGANOX® 1010 comprises pentaerythritol tetrakis(3-(3,5-di-t-butyl-4-hydroxyphenyl)propionate). Examples of UV absorbers include phenol, 2-(2H-benzotriazol-2-yl)-6-dodecyl-4-methyl-, branched and linear (TINUVIN® 571). Examples of UV stabilizers include bis(1,2,2,6,6-pentamethyl-4-piperidyl) sebacate; methyl 1,2,2,6,6-pentamethyl-4-piperidyl/sebacate; and a combination thereof (TINUVIN® 272). These and other TINUVIN® additives, such as TINUVIN® 765 are commercially available from Ciba Specialty Chemicals of Tarrytown, N.Y., U.S.A. Other UV and light stabilizers are commercially available, and are exemplified by LowLite from Chemtura, OnCap from PolyOne, and Light Stabilizer 210 from E. I. du Pont de Nemours and Company of Delaware, U.S.A. Oligomeric (higher molecular weight than monomeric) stabilizers may alternatively be used, for example, to decrease or minimize potential for migration of the stabilizer out of the curable polyorganosiloxane composition or the cured silicone product thereof. An example of an oligomeric antioxidant stabilizer (specifically, hindered amine light stabilizer (HALS)) is Ciba TINUVIN® 622, which is a dimethylester of butanedioic acid copolymerized with 4-hydroxy-2,2,6,6-tetramethyl-1-piperidine ethanol. Heat stabilizers may include iron oxides and carbon blacks, iron carboxylate salts, cerium hydrate, barium zirconate, cerium and zirconium octanoates, and porphyrins.

The amount of ingredient (K) depends on various factors including the specific anti-aging additive selected and the anti-aging benefit desired. However, the amount of ingredient (K) may range from 0 to 5%, alternatively 0.1% to 4%, and alternatively 0.5% to 3%, based on the combined weight of all ingredients in the curable polyorganosiloxane composition. Ingredient (K) may be one anti-aging additive. Alternatively, ingredient (K) may comprise two or more different anti-aging additives.

Ingredient (L) is a pigment. For purposes of this application, the term ‘pigment’ includes any ingredient used to impart color to a reaction product of a composition described herein. The amount of pigment depends on various factors including the type of pigment selected and the desired degree of coloration of the cured silicone product. For example, the composition may comprise 0 to 20%, alternatively 0.001% to 5%, of a pigment based on the combined weight of all ingredients in the curable polyorganosiloxane composition.

Examples of suitable pigments include indigo, titanium dioxide Stan-Toner™ 50SP01 Green (which is commercially available from PolyOne Corporation, Avon Lake, Ohio, U.S.A.) and carbon black. Representative, non-limiting examples of carbon black include Shawinigan Acetylene black, which is commercially available from Chevron Phillips Chemical Company LP; SUPERJET® Carbon Black (LB-1011) supplied by Elementis Pigments Inc., of Fairview Heights, Ill. U.S.A.; SR 511 supplied by Sid Richardson Carbon Co, of Akron, Ohio U.S.A.; and N330, N550, N762, N990 (from Degussa Engineered Carbons of Parsippany, N.J., U.S.A.).

When selecting ingredients for the silicone composition described above, there may be overlap between types of ingredients because certain ingredients described herein may have more than one function. For example, certain alkoxysilanes may be useful as filler treating agents and as adhesion promoters. Certain particulates may be useful as fillers and as pigments, e.g., carbon black. When adding additional ingredients to the silicone composition, and to the curable polyorganosiloxane composition, the additional ingredients are distinct from one another.

The silicone composition can be prepared by a method comprising combining the shrink additive and all ingredients of the curable polyorganosiloxane composition by any convenient means such as mixing at ambient or elevated temperature. The stabilizer, when present, may be added before the catalyst, for example, when the silicone composition will be prepared at elevated temperature and/or the silicone composition will be prepared as a one part composition.

When the filler-treating agent is present, the silicone composition may optionally be prepared by surface treating a particulate ingredient (e.g., filler and/or spacer, if present) with the filler-treating agent, optionally in the presence of the shrink additive, and thereafter mixing the product thereof with the other ingredients of the silicone composition.

Alternatively, the silicone composition may be prepared as a multiple part composition, for example, when the stabilizer is absent, or when the silicone composition will be stored for a long period of time before use. In the multiple part composition, the catalyst is stored in a separate part from any ingredient having a silicon-bonded hydrogen atom, for example ingredient (C), and the parts are combined shortly before use of the silicone composition. For example, a two part composition may be prepared by combining ingredients comprising ingredient (B), ingredient (A), optionally the filler, and optionally one or more other additional ingredients described above to form a base by any convenient means such as mixing. A curing agent may be prepared by combining ingredients comprising ingredient (B), ingredient (C), and optionally one or more other additional ingredients described above by any convenient means such as mixing. The shrink additive may be added to either the base or the curing agent, or both. The ingredients may be combined at ambient or elevated temperature. When a two part composition is prepared, the weight ratio of amounts of base to curing agent may range from 1:1 to 10:1.

The curable polyorganosiloxane composition in the silicone composition will cure to form a cured silicone product, and the cured silicone product will shrink as the shrink additive is removed during the method described herein. Removing the shrink additive reduces bondline thickness (BLT) of the cured silicone product in the z-direction (e.g., the distance between the substrate and the IHS and/or the distance between the heat-generating electronic component and the IHS, when the cured silicone product will be used as a TIM). The amount of shrinkage may be at least 5%, alternatively at least 5% and at most 75%, alternatively 5% to 70%, alternatively 10% to 70%, alternatively 10% to 60%, alternatively 10% to 50%, and alternatively 15% to 70% of the BLT in the z-direction of the silicone composition before removal of the shrink additive. For example, thickness of the first cured silicone product, after step 3), may be reduced 5% to 70% as compared to thickness of the first silicone composition comprising the first shrink additive and the first curable polyorganosiloxane composition in step 1).

The curable polyorganosiloxane composition may be cured, and the shrink additive may be removed, by heating. For example, the silicone composition may be heated at constant temperature of 140° C. to 170° C. for at least 2 hours, for example, in an isothermal convection oven. Alternatively, a step method may be used, such as by heating from room temperature to 85° C., holding the temperature at 85° C. for 15 minutes to 1 hr (alternatively 30 min), increasing the temperature to 90° C. and holding the temperature at 90° C. for 1 hr to 2 hr, alternatively 90 minutes. The curable polyorganosiloxane composition may alternatively be cured, and the shrink additive may be removed, using a reflow oven, which is an oven where the electronic component with the silicone composition applied thereto travel through the oven using a modified step cure with multiple heating zones. These heating profiles are meant to be exemplary and not limiting of the invention set forth in the claims.

The cured silicone product of the method described herein, may be used as a TIM, a Lid Seal Adhesive, or as a combination of a TIM and a Lid Seal Adhesive. When the cured silicone product will be used to adhere two or more electronic components together in an electronic device, the curable polyorganosiloxane composition may include ingredients (A), (B), (C), and (H). This curable polyorganosiloxane composition may optionally further include one or more of ingredients (D), (E) and (F). When the cured silicone product will be used for TIM applications, the curable polyorganosiloxane composition includes ingredient (E3) a thermally conductive filler at a high loading, i.e., a quantity sufficient to enhance conduction of heat through the second silicone composition, e.g., 50 vol % to 80 vol % based on the total volume of all ingredients in the curable polyorganosiloxane composition.

When the curable polyorganosiloxane composition will be used to form a TIM, the curable polyorganosiloxane composition may include ingredients (A), (B), (C), (E), and (F). The curable polyorganosiloxane composition for TIM applications may further include ingredient (H). Because the cured silicone product for TIM applications is thermally conductive, in this curable polyorganosiloxane composition ingredient (E) is a thermally conductive filler at loading, i.e., a quantity sufficient to enhance conduction of heat through the second silicone composition, e.g., 50 vol % to 80 vol % based on the total volume of all ingredients in the curable polyorganosiloxane composition. A thermally conductive curable polyorganosiloxane composition (a thermally conductive curable adhesive composition) may be prepared by including ingredients (A), (B), (C), (E), (F), (G), and (H).

The silicone composition described above may be used to form a TIM, for example, when the curable polyorganosiloxane composition (in the silicone composition) includes a thermally conductive filler as described above. A method of forming the TIM may comprise:

i) interposing the silicone composition described above along a thermal path between a heat-generating electronic component and a heat dissipater,

ii) curing the curable polyorganosiloxane composition, and

iii) removing the second shrink additive; thereby forming the thermally conductive second cured silicone product in the form of a thermal interface material. The heat dissipater may be the IHS described above.

In step i), the silicone composition can be applied either to the heat-generating electronic component and thereafter to the heat dissipater (e.g., IHS, heat spreader, or heat sink); or the silicone composition can be applied to the heat dissipater and thereafter to the heat-generating electronic component, or the silicone composition can be applied to the heat-generating electronic component and heat dissipater simultaneously. Steps ii) and iii) may be performed by heating. Heating may be performed to cure the curable polyorganosiloxane composition. Heating may be performed to remove the shrink additive. Conditions for curing the curable polyorganosiloxane composition and conditions for removing the shrink additive are as described above.

An electronic device comprises:

a) a heat-generating electronic component,

b) a thermal interface material described above, and

c) a heat dissipater;

where the thermal interface material is positioned between the heat-generating electronic component and the heat dissipater along a thermal path extending from a surface of the heat-generating electronic component to a surface of the heat dissipater. The electronic device may be made by the method of fabricating.

In the methods and electronic devices described herein, the heat-generating electronic component may be, for example, a memory cache, a semiconductor, a transistor, an integrated circuit, or a discrete device. The heat dissipater may comprise a heat sink, a heat spreader, or an IHS; such as a thermally conductive plate, a thermally conductive cover or lid, a fan, a circulating coolant system, or a combination thereof.

Alternatively, the silicone composition described above may be used to form a cured silicone product that bonds two or more components together in the electronic device, for example, when the curable polyorganosiloxane composition includes an adhesion promoter. For example, the silicone composition and method described above may be used to form a lid seal adhesive. E.g., the first cured silicone product may form, or constitute, a lid seal adhesive, e.g., the first cured silicone product may form, or constitute, a lid seal adhesive between the lid and the substrate. The curable polyorganosiloxane composition may be filled or unfilled when used to bond two or more components together in the electronic device. When the cured silicone product will be used to bond components together, the curable polyorganosiloxane composition may include an adhesion promoter, as described above. Alternatively, the cured silicone product may be a thermally conductive adhesive, which may be prepared by including both an adhesion promoter and a thermally conductive filler in the curable polyorganosiloxane composition described above. The first cured silicone product may form a lid seal adhesive, and the thermally conductive second cured silicone product may form a thermal interface material, and the electronic device is a multichip package.

An embodiment of the present invention is a multichip package using the cured silicone product and method described herein. Such multichip package may comprise: a first heat-generating electronic component mounted to a substrate; a second heat-generating electronic component mounted to the substrate adjacent to the first heat-generating electronic component; an integrated heat spreader (IHS) mounted to the substrate so as to at least partially cover the first heat-generating electronic component and the second-heat-generating electronic component; where at least one of conditions (A) to (C) is satisfied:
(A) the multichip package further comprises a lid seal adhesive and the IHS is connected to the substrate through the lid seal adhesive, which is formed by the method of fabricating; or
(B) the multichip package further comprises a thermal interface material and the IHS is connected to at least one of the first heat-generating electronic component and the second heat-generating electronic component through the thermal interface material, which is formed by the method of fabricating, or
(C) the multichip package further comprises a thermally conductive lid seal adhesive and the IHS is connected to the substrate through the thermally conductive lid seal adhesive, which is formed by the method of fabricating;
   wherein each of the lid seal adhesive of (A), thermal interface material of (B), and thermally conductive lid seal adhesive of (C) is formed by curing a curable polyorganosiloxane composition in a silicone composition comprising a shrink additive and the curable polyorganosiloxane composition and removing the shrink additive as described throughout this specification. Condition (A) may be satisfied, alternatively condition (B) may be satisfied, alternatively condition (C) may be satisfied, alternatively both conditions (A) and (B) may be satisfied, alternatively both conditions (B) and (C) may be satisfied, alternatively both conditions (A) and (B) are satisfied and condition (C) is not satisfied, alternatively both conditions (B) and (C) are satisfied and condition (A) is not satisfied. The heat-generating electronic component mentioned in earlier paragraphs may be the first heat-generating electronic component of condition (B) or the second heat-generating electronic component of condition (B).

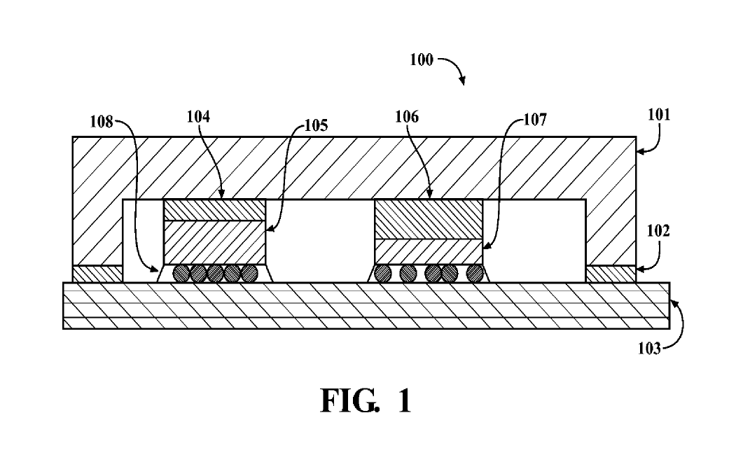

FIG. 1 shows an exemplary multi-chip package 100 fabricated using the cured silicone product and method described herein. The multi-chip package 100 includes an electronic component that is a CPU 105 attached to a substrate (shown as a circuit board) 103 through a solder-containing underfill 108. The CPU 105 is thermally connected to a lid 101 by a first thermal interface material 104. The CPU 105 may be off center on the substrate 103. The multi-chip package further includes a memory cache 107 attached to the substrate 103 through a second solder-containing underfill 108 adjacent to the CPU 105. The memory cache 107 is thermally connected to the lid 101 by a second thermal interface material 106. The lid 101 is adhered to the substrate 103 by a lid seal 102.

The multi-chip package 100 shown in FIG. 1 may be fabricated in a method including: 1) applying the silicone composition (including a thermally conductive filler) to the memory cache 107, or to the portion of the lid 101 that the memory cache 107 will sit under when the lid 101 is closed; and applying a silicone composition (including an adhesion promoter) to either the perimeter of the lid 101, or to the portion of substrate 103 to which the lid 101 will adhere when the lid 101 is closed. The lid 101 may then be closed (i.e., connected to the substrate 103). The multi-chip package 100 may then be heated to cure the curable polyorganosiloxane composition. The multi-chip package 100 may then be further heated to remove the shrink additive by the method described above. The lid seal 102 and the second thermal interface material 106 are thereby formed, and are both cured silicone products prepared by the method described herein.

The first thermal interface material 104 may be either a solder TIM (sTIM) or polymeric TIM (pTIM) depending on the thermal requirements and heat generated. Without wishing to be bound by theory, it is thought that memory components such as the memory cache 107 do not generate as much heat as the CPU 105, and therefore, the second thermal interface material 106 can be of lower thermal conductivity than the thermal conductivity of the first thermal interface material 104.

Using a thermally conductive adhesive prepared as the cured silicone product by the method described above for both the lid seal 102 and the second thermal interface material 106 may provide the benefit of using a single dispense equipment. The thermally conductive adhesive would have higher modulus (than modulus of current commercially available materials made without a shrink additive) to provide the multi-chip package 100 with stiffness to mitigate warpage. A thermally conductive adhesive can function as both a lid seal adhesive 102 to adhere the lid 101 to the memory cache 107 and also as a thermal interface material 106 to dissipate heat from the memory cache 107 to the lid 101, which also acts as a heat spreader. The multichip package 100 is relatively large and may have an off-center CPU 105. The stiffness of the TIM 106 on the memory component 107 may reduce the warpage on the first thermal interface material 104. Such a solution may provide a benefit for package warpage control when a pTIM is used for the first thermal interface material 104 on the CPU 105. The compressive force generated as a result of the shrink additive being removed in the method described above may provide the benefit of maintaining the multi-chip package 100 in compression. Applying pressure on the TIM may provide the benefits of increasing thermal efficiency and reducing thermal resistance.

When an sTIM is used for thermal management, the shrinkage of the second thermal interface material 106 would permit the collapse of the sTIM during the solder reflow of an Indium sTIM. The sTIM would shrink from a bondline of, for example, 0.229 mm to 0.178 mm (9 mils to 7 mils). Such a collapse is not attained when a curable silicone composition without a shrink additive is used on the memory cache 107. However, the shrinkage of the silicone composition when the shrink additive leaves to form the second thermal interface material 106 will permit such a collapse of the sTIM. Curing the curable polyorganosiloxane composition and reflowing the sTIM can occur separately, or can occur during the same heating step.

### Examples

In these examples, “8-0080” refers to DOW CORNING® 8-0080, which is a mixture of vinyl-terminated polydimethylsiloxane and vinyl functional siloxane resin commercially available from Dow Corning Corporation of Midland, Mich., U.S.A. “Min-U-Sil®” refers to 5 um silica, “Cab-O-Sil® M-7D” refers to fumed silica, and “TS-530” refers to Cab-O-Sil® TS-530 fumed silica, all of which are commercially available from Cabot Corporation of Boston, Mass., U.S.A. “W-1011” refers to a carbon black pigment, which is commercially available from SID RICHARDSON CARBON COMPANY. “2-0707” refers to DOW CORNING® 2-0707, which is a platinum catalyst commercially available from Dow Corning Corporation. “6-3570” refers to DOW CORNING® 6-3570, which is a trimethylsiloxy-terminated poly(dimethyl,methylhydrogen siloxane) commercially available from Dow Corning Corporation. “PJ Fluid” refers to DOW CORNING® 4-2783, which is a hydroxy-terminated poly(methylvinylsiloxane) commercially available from Dow Corning Corporation. “IP Mixture” refers to IP Mixture 2028 commercially available from Idemitsu Kosan Co., Ltd. of Tokyo, Japan. “SFD-117” refers to DOW CORNING® SFD-117, which is a vinyl-terminated polydimethylsiloxane commercially available from Dow Corning Corporation. “Pigment” is a mixture of 10% to 14% zinc oxide, 4% to 8% carbon black, and 72% to 92% vinyl terminated polydimethylsiloxane. “4-7042” refers to DOW CORNING® 4-7042, which is a mixture of hydroxy-terminated, poly(dimethyl, methylvinyl siloxane) and alpha-hydroxy-terminated, omega-methoxy-terminated, poly(dimethyl, methylvinyl siloxane) commercially available from Dow Corning Corporation. “1-4173” refers to DOW CORNING® 1-4173 Thermally Conductive Adhesive, which is commercially available from Dow Corning Corporation.

In comparative example 1 and example 1, samples were prepared by mixing the ingredients shown below in Table 1 in the order listed.

TABLE 1
Comparative Example 1 and Example 1

| | Amounts (parts by weight) | |
|---|---|---|
| Ingredients | Comparative Example 1 | Example 1 |
| 8-0080 | 52.1 | 46.9 |
| Min-U-Sil ® | 33.3 | 30.0 |
| Cab-O-Sil ® M-7D | 5.0 | 4.5 |
| W-1011 | 0.3 | 0.3 |
| Methyl butynol | 0.2 | 0.2 |
| 2-0707 | 0.2 | 0.1 |
| 6-3570 | 6.5 | 5.9 |
| 4-2783 | 1.2 | 1.1 |
| Glycidoxypropyltrimethoxysilane | 1.2 | 1.1 |
| IP Mixture | 0 | 9.0 |
| Additional Cab-O-Sil ® M-7D | 0 | 1.0 |

In example 2, silicone composition samples were prepared by mixing the ingredients shown below in Table 2.

TABLE 2
Example 2

| Ingredients | Amount (parts by weight) |
|---|---|
| SFD-117 | 11.8 |
| Pigment | 0.1 |
| Methyltrimethoxysilane | 0.2 |
| CB-A20S | 40.5 |
| Al-43-Me | 40.6 |
| TS-530 | 1.1 |
| IP Mixture | 3.5 |
| Glycidoxypropyltrimethoxysilane | 0.6 |
| 4-7042 | 0.6 |
| Phenyl butynol | 0.1 |
| 6-3570 | 0.7 |
| 2-0707 | 0.1 |

In example 3, different amounts of IP Mixture were added to the curable polyorganosiloxane composition of Comparative Example 1, described above; and to samples of 1-4173. The amounts of each curable polyorganosiloxane composition and the shrink additive are shown in Table 3.

TABLE 3

| | | Amount of IP Mixture | | |
|---|---|---|---|---|
| Samples | Curable | add to the Curable | Trial 1 (% | Trial 2 (% |
| prepared in | Polyorganosiloxane | Polyorganosiloxane | change in | change in |
| Example 3 | Composition | Composition (Wt %) | BLT) | BLT) |
| 1 (comparative) | 1-4173 | 0 | Not tested | −21.5 |
| 2 | 1-4173 | 1.95 | −30 | −26 |
| 3 | 1-4173 | 4.12 | −45 | Not |
| | | | | recorded |
| 4 | 1-4173 | 6.55 | −81.75 | −76 |
| 5 (comparative) | Comparative Ex. 1 | 0 | −11 | −10 |
| 6 | Comparative Ex. 1 | 4.74 | −20 | −21 |
| 7 | Comparative Ex. 1 | 10.0 | −44.5 | −23.5 |
| 8 | Comparative Ex. 1 | 15.9 | −44 | −57.5 |

In example 3, samples were interposed between two substrates and cured by heating at 150° C. for 2 h. The BLT was measured before heating and after heating. The difference in BLT was reported as % change in Table 3. Each trial was repeated two times.

In example 4, physical properties were measured on the cured silicone products prepared as in comparative example 1 and example 1. The results, which are in Table 4, show that the use of the shrink additive does not significantly affect physical properties of the cured silicone product. E.g., the physical properties may be affected by less than 35% (e.g., viscosity), alternatively <20% (e.g., durometer), alternatively <10% (e.g., tensile, elongation, and/or thixo ratio), alternatively <1% (e.g., specific gravity)

TABLE 4
Physical Properties

| | | | Comparative | Example |
|---|---|---|---|---|
| Property | Units | ASTM | Example 1 | 1 |
| Durometer | Shore A | D-2240 | 60 | 71 |
| Tensile | PSI | D-412 | 772 | 730 |
| Elongation | % | D-412 | 200 | 188 |
| Specific Gravity | g/cm³ | D-4287 | 1.34 | 1.35 |
| Viscosity | Poise | D-1084 | 2258 | 1680 |
| Thixo Ratio | NA | D-1084 | 4.46 | 5.00 |

With respect to any Markush groups relied upon herein for describing particular features or aspects of various embodiments, it is to be appreciated that different, special, and/or unexpected results may be obtained from each member of the respective Markush group independent from all other Markush members. Each member of a Markush group may be relied upon individually and or in combination and provides adequate support for specific embodiments within the scope of the appended claims.

It is also to be understood that any ranges and subranges relied upon in describing various embodiments of the present disclosure independently and collectively fall within the scope of the appended claims, and are understood to describe and contemplate all ranges including whole and/or fractional values therein, even if such values are not expressly written herein. The enumerated ranges and subranges sufficiently describe and enable various embodiments of the present disclosure, and such ranges and subranges may be further delineated into relevant halves, thirds, quarters, fifths, and so on. As just one example, a range “of 200 to 1400” may be further delineated into a lower third, i.e., from 200 to 600, a middle third, i.e., from 600 to 1000, and an upper third, i.e., from 1000 to 1400, which individually and collectively are within the scope of the appended claims, and may be relied upon individually and/or collectively and provide adequate support for specific embodiments within the scope of the appended claims. In addition, with respect to the language which defines or modifies a range, such as “at least,” “greater than,” “less than,” “no more than,” and the like, it is to be understood that such language includes subranges and/or an upper or lower limit. As another example, a range of “at least 0.1%” inherently includes a subrange from 0.1% to 35%, a subrange from 10% to 25%, a subrange from 23% to 30%, and so on, and each subrange may be relied upon individually and/or collectively and provides adequate support for specific embodiments within the scope of the appended claims. Finally, an individual number within a disclosed range may be relied upon and provides adequate support for specific embodiments within the scope of the appended claims. For example, a range of “1 to 9” includes various individual integers, such as 3, as well as individual numbers including a decimal point (or fraction), such as 4.1, which may be relied upon and provide adequate support for specific embodiments within the scope of the appended claims.

The subject matter of all combinations of independent and dependent claims, both singly and multiply dependent, is expressly contemplated but is not described in detail for the sake of brevity. The disclosure has been described in an illustrative manner, and it is to be understood that the terminology which has been used is intended to be in the nature of words of description rather than of limitation. Many modifications and variations of the present disclosure are possible in light of the above teachings, and the disclosure may be practiced otherwise than as specifically described. The following claims 1 to 15 are incorporated here by reference as numbered aspects wherein “claim” and “claims” are replaced with “aspect” and “aspects,” respectively.

1. A method of fabricating an electronic device, the method comprises the steps of:
1) interposing a first silicone composition comprising
I) a first shrink additive, and
II) a first curable polyorganosiloxane composition;
between an integrated heat spreader (IHS) and a substrate,
2) curing the first curable polyorganosiloxane composition to form a first cured silicone product,
3) removing the first shrink additive during and/or after step 2), thereby compressing the IHS on the substrate.

2. The method of claim 1, further comprising the steps of:
1′) interposing a second silicone composition comprising
I) a second shrink additive, and
II) a thermally conductive second curable polyorganosiloxane composition between a heat-generating electronic component and a heat dissipater in the electronic device;
wherein step 2) also cures the thermally conductive second curable polyorganosiloxane composition, and
step 3) also removes the second shrink additive, thereby compressing the heat-generating electronic component and the heat dissipater.

3. The method of claim 1 or claim 2, where the first shrink additive and/or the second shrink additive is an iso-alkane of at least 10 carbon atoms.

4. The method of claim 1, where the first curable polyorganosiloxane composition comprises:
(A) a catalyst, and
(B) an aliphatically unsaturated polyorganosiloxane having an average, per molecule, of one or more aliphatically unsaturated organic groups capable of undergoing a curing reaction, with the proviso that when ingredient (B) does not contain a silicon-bonded hydrogen atom, then the composition further comprises ingredient (C), an SiH functional compound having an average, per molecule, of one or more silicon-bonded hydrogen atoms, which is distinct from ingredients (A) and (B).

5. The method of claim 2, where the thermally conductive curable polyorganosiloxane composition comprises:
(A) a catalyst,
(B) an aliphatically unsaturated polyorganosiloxane having an average, per molecule, of one or more aliphatically unsaturated organic groups capable of undergoing a curing reaction, with the proviso that when ingredient (B) does not contain a silicon-bonded hydrogen atom, then the composition further comprises ingredient (C), an SiH functional compound having an average, per molecule, of one or more silicon-bonded hydrogen atoms, which is distinct from ingredients (A) and (B), and
(E3) a thermally conductive filler.

6. The method of claim 4 or claim 5, where the first curable polyorganosiloxane composition further comprises an ingredient selected from (D) a spacer; (E) a filler; (F) a filler treating agent; (G) a stabilizer, (H) an adhesion promoter; (J) a flux agent; (K) an anti-aging additive; (L) a pigment; and a combination thereof, provided, however, that (E) a filler is different from (E3) a thermally conductive filler when the thermally conductive curable polyorganosiloxane composition comprises (E) a filler.

7. The method of claim 1 or claim 2, where step 3) is performed both during and after step 2).

8. The method of claim 1 or claim 2, where step 3) is performed substantially after step 2).

9. The method of claim 1, where thickness of the first cured silicone product, after step 3), is reduced 5% to 70% as compared to thickness of the first silicone composition comprising the first shrink additive and the first curable polyorganosiloxane composition in step 1).

10. The method of claim 2, where the heat dissipater is the IHS.

11. The method of claim 1 or claim 10, where the IHS is a lid, and the first cured silicone product forms a lid seal adhesive between the lid and the substrate.

12. The method of claim 10, where the method forms a thermally conductive second cured silicone product between the heat-generating electronic component and the IHS.

13. The method of claim 12, where the first cured silicone product forms a lid seal adhesive, and the thermally conductive second cured silicone product forms a thermal interface material, and the electronic device is a multichip package.

14. A multichip package comprising:
a first heat-generating electronic component mounted to a substrate,
a second heat-generating electronic component mounted to the substrate adjacent to the first heat-generating electronic component,
an integrated heat spreader (IHS) mounted to the substrate so as to at least partially cover the first heat-generating electronic component and the second heat-generating electronic component,
where at least one of conditions (A) to (C) is satisfied:
(A) the multichip package further comprises a lid seal adhesive and the IHS is connected to the substrate through the lid seal adhesive, which is formed by the method of claim 11, or
(B) the multichip package further comprises a thermal interface material and the IHS is connected to at least one of the first heat-generating electronic component and the second heat-generating electronic component through the thermal interface material, which is formed by the method of claim 12, or
(C) the multichip package further comprises a thermally conductive lid seal adhesive and the IHS is connected to the substrate through the thermally conductive lid seal adhesive, which is formed by the method of claim 11.

15. The multichip package of claim 14, where both conditions (A) and (B) are satisfied; or where both conditions (B) and (C) are satisfied.
